(19) United States
(12) Patent Application Publication
(10) Pub. No.: US 2003/0113997 A1
(43) Pub. Date: Jun. 19, 2003

(54) METHOD OF FORMING A METAL INTERCONNECT

(76) Inventors: Yung-Chih Lai, Nan-Tou Hsien (TW); Yao-Lien Pu, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/683,339

(22) Filed: Dec. 17, 2001

(51) Int. Cl. H01L 21/4763

(52) U.S. Cl. 438/669

(57) ABSTRACT

A semiconductor substrate has a first dielectric layer positioned on the semiconductor substrate. At least one recess is formed in the first dielectric layer. Then a glue layer, a metal layer and a material layer, sealing an opening of the recess, are sequentially formed on the surface of the recess. Thereafter, a photo-etching-process is performed to form at least one metal interconnect in the glue layer, the metal layer and the material layer. The material layer that seals the opening of the recess is used to prevent portions of a photoresist layer from remaining in the recess during the photo-etching-process.

### BACKGROUND OF INVENTION

1. Field of the Invention

The present invention relates to a method of forming a metal interconnect, and more particularly, to a method of forming a metal interconnect without residual photoresist in the metal interconnect.

2. Description of the Prior Art

In advanced very large scale integrated circuits (VLSI) technology, process has been upgraded to the extent which several hundred thousands, or even several millions devices, such as the metal oxide semiconductor (MOS) transistors, are accumulated on a surface of a 1˜2 cm² silicon area. A metallization process and a metal interconnect process are used not only to connect devices, such as three electrodes in previously mentioned MOS transistor and metal layer and metal layer, but also to electrically connect those metal lines, which contact each MOS device, according to the layout of circuit designto form a complete circuit and constitute an entire electrical device.

In modern VLSI processes, tungsten (W) and aluminum-silicon-copper alloy (Al—Si—Cu alloy) are commonly used as conductive materials for contacts and interconnects. Tungsten, being less sensitive to a high temperature process and having an excellent step coverage ability, is frequently formed in a low pressure chemical vapor deposition (LPCVD) process and is very suitable for a high temperature resisting metal interconnect. However, the drawback to tungsten is its high cost. Al—Si—Cu alloy is normally formed in a DC sputtering process, and is with good conductivity and, however, a lower melting point (the melting point for aluminum is approximately 577° C.). Other conductive materials, comprising titanium (Ti), titanium silicide (TiSi₂), tungsten silicide (WSiₓ), titanium nitride (TiN) and titanium tungsten alloy (TiW alloy), are occasionally employed as well. Titanium, titanium silicide and tungsten silicide are mostly used for reducing either the contact resistance of the metal and each electrode of the MOS transistor, or the resistivity for each metal line. On the other hand, titanium nitride and titanium tungsten alloy are commonly used to prevent the formation of a metal silicide barrier layer in the interface of the metal and the silicon, or are used as a glue layer for improving the adhesion between metal and other materials.

Please refer to FIG. 1 to FIG. 5 of schematic diagrams of a method for forming either a metal interconnect 24 or a via plug according to the prior art. As shown in FIG. 1, a semiconductor wafer 10 comprises a substrate 12 and a first dielectric layer 14 covering the substrate 12. First, a photoresist layer 15 is coated on the surface of the first dielectric layer 14 followed by performing a photolithography process to define the site and dimensions for a recess in the photoresist layer 15. Then a dry etching process is performed to vertically remove portions of the first dielectric layer 14 along the defined pattern down to a surface of the substrate 12, so that a via hole 16 with two vertical side walls are formed. It is worth noticing that normally a metal layer (not shown) is on portions of the surface of the substrate 12 underneath the via hole 16. The same process is also applied in the formation of a contact hole with a source (not shown), a drain (not shown) or a gate (not shown) of a MOS transistor on portions of the surface of the substrate 12 underneath the contact hole.

As shown in FIG. 2, a first titanium nitride layer 18 is formed in the via hole 16 and atop the first dielectric layer 14 thereafter. A titanium silicide (TiSi₂) layer is commonly comprised between the first titanium nitride layer 18 and the silicon substrate 12. The first titanium nitride layer 18, formed by a nitridation process or a reactive sputtering process, is used as a glue layer. The nitridation process is to deposit a titanium layer with a specific thickness on a surface of a wafer by a DC Magnetron Sputter method, and then place the wafer in an environment containing nitrogen or ammonia to nitridize the titanium layer to a titanium nitride layer at a high temperature. On the other hand, the reactive sputtering process is to perform an ion bombardment process to sputter the titanium atoms from the titanium target by utilizing a reactive gas mixed with argon and nitrogen. Then the titanium atoms react with the nitrogen atoms dissociated from the plasma and a titanium nitride deposition process therefore progresses on the wafer surface. Thereafter, a chemical vapor deposition (CVD) process is performed to deposit a tungsten layer (W layer) 22 with good step coverage on the first titanium nitride layer 18.

As shown in FIG. 3, then a first photolithography process is performed to form a patterned photoresist layer 23 on the tungsten layer 22 to define a pattern of a metal interconnect. Thereafter, a dry etching process is performed to remove portions of the tungsten layer 22 and portions of the titanium nitride layer 18, both portions being not covered by the photoresist layer 23, to form a metal interconnect 24. Since the step coverage ability of the tungsten layer 22 is very well, an opening of the via hole 16 is not sealed by the deposited tungsten layer 22 without a sufficient thickness. Therefore, portions of the photoresist layer 23 enters the via hole 16 during the formation of the photoresist layer 23. As shown in FIG. 4, portions of the photoresist layer 23 thus remains in the via hole 16 after the photoresist layer 23 is removed.

As shown in FIG. 5, a deposition process is then performed to form a second dielectric layer 26. Due to the residual portions of the photoresist layer 23, composed of polymers that change in both physical and chemical properties during the deposition process, in the via hole 16, abnormal phenomena, such as particles, defects and bubbles, occur during the deposition process. In order to resolve this problem, a modified process is proposed.

Please refer to FIG. 6 to FIG. 11 of schematic diagrams of a modified method for forming a metal interconnect 46 according to the prior art. As shown in FIG. 6, a semiconductor wafer 30 comprises a substrate 32 and a first dielectric layer 34 covering the substrate 32. First, a photoresist layer 35 is coated on the surface of the first dielectric layer 34 followed by performing a photolithography process to define the site and dimensions of a recess in the photoresist layer 35. Then a dry etching process is performed to vertically remove portions of the first dielectric layer 34 along the defined pattern down to the surface of the substrate 32, so that a via hole 36 with two vertical side walls are formed. It is worth noticing that a metal layer (not shown) is on portions of the surface of the substrate 32 underneath the via hole 36 in other circumsances. The same process is applied as well in the formation of a contact hole with a source (not shown), a drain (not shown) or a gate (not shown) of a MOS transistor on portions of the surface of the substrate 32 underneath the contact hole.

As shown in FIG. 7, thereafter, a first titanium nitride layer 38, employed as a glue layer, is formed in the via hole 36 and atop the first dielectric layer 34 by performing a nitridation process or a reactive sputtering process. The nitridation process is to deposit a titanium layer with a specific thickness on a surface of a wafer by utilizing a DC Magnetron Sputter method first, and then place the wafer in an environment containing nitrogen or ammonia to nitridize the titanium layer to a titanium nitride layer at a high temperature. On the other hand, the reactive sputtering process is to ion bombard the titanium target to sputter the titanium atoms by utilizing a reactive gas mixed with argon and nitrogen. Then the titanium atoms react with the nitrogen atoms dissociated from the plasma and a titanium nitride deposition process therefore progresses on the wafer surface. Thereafter, a first chemical vapor deposition (CVD) process is performed to deposit a tungsten layer (W layer) 42 with excellent step coverage ability on the first titanium nitride layer 38. In this modified process, the thickness of the tungsten layer 42 is greater than the thickness of the tungsten layer 22 in the previous embodiment of the prior art, and the tungsten layer 42 is used as a via plug.

As shown in FIG. 8, an etching back process, alternatively a chemical mechanical polish (CMP) process, is performed to remove portions of the tungsten layer 42 by utilizing the first titanium nitride layer 38 as a stop layer to make a surface of the remaining portions of the tungsten layer 42 in the via hole 36 approximately align with the surface of the first titanium nitride layer 38 after the etching back process is performed. Then, as shown in FIG. 9, a second chemical vapor deposition (CVD) process is performed to form a tungsten layer 44 atop the first titanium nitride layer 38 and the tungsten layer 42 for use as a metal interconnect.

As shown in FIG. 10, a photolithography process is performed thereafter to form a patterned photoresist layer 45 on the tungsten layer 44 to define a pattern of a metal interconnect 46. Then, a dry etching process is performed to remove portions of the tungsten layer 44 and portions of the first titanium nitride layer 38, both portions being not covered by the photoresist layer 45, and thus form the metal interconnect 46. A void is formed in the via hole 36 during the formation of the tungsten layer 42 due to the excellent step coverage ability of the tungsten layer 42. In the prior art shown in FIG. 6 to FIG. 11, an etching back process, alternatively a chemical mechanical process, is performed first, and then the tungsten layer 44 connecting with the tungsten layer 42 is deposited to prevent the photoresist layer 45 from entering the via hole 36 through the void. Remaining portions of the photoresist layer 45 the via hole 36 after removing the photoresist layer 45, are thus prevented. As shown in FIG. 11, finally, a deposition process is performed to form a second dielectric layer 48. Since no residual photoresist is in the via hole 36, abnormal phenomena, such as particles, defects and bubbles, are effectively prevented.

However, the modified process causes several problems, such as the expensive price of the tungsten material that results in a higher cost, difficulty in controlling yield due to residue and defect that occurs during either the etching back process or the chemical mechanical polish process for the tungsten layer. Therefore, another modified process is proposed.

Please refer to FIG. 12 to FIG. 15 of schematic diagrams of another modified method for forming a metal interconnect 78 according to the prior art. As shown in FIG. 12, a semiconductor wafer 60 comprises a substrate 62 and a first dielectric layer 64 covering the substrate 62. First, a photoresist layer 65 is coated on the surface of the first dielectric layer 64 followed by performing a photolithography process to define the site and dimensions of a recess in the photoresist layer 65. Then, a dry etching process is performed to vertically remove portions of the first dielectric layer 64 along the defined pattern down to the surface of the substrate 62, so that a via hole 66 with two vertical side walls are formed. It is worth noticing that a metal layer (not shown) is on portions of the surface of the substrate 62 underneath the via hole 66 in other circumsances. The same process is applied as well in the formation of a contact holewith a source (not shown), a drain (not shown) or a gate (not shown) of a MOS transistor on portions of the surface of the substrate 62 underneath the contact hole.

As shown in FIG. 13, thereafter, a first titanium nitride layer 68, used as a glue layer, is formed in the via hole 66 and atop the first dielectric layer 64. Then a chemical vapor deposition (CVD) process is performed to form a tungsten layer (W layer) 72 with good step coverage ability on the first titanium nitride layer 68. The thickness of the tungsten layer 72 in this modified method is greater than the thicknesses of the tungsten layers in the previously mentioned embodiments, and the tungsten layer 72 is used as both a via plug and a metal interconnect. The etching back process, the chemical mechanical polishing process and the deposition of another tungsten layer in the previously mentioned embodiments are thus omitted.

As shown in FIG. 14, a first photolithography process is performed to form a patterned photoresist layer 73 atop the tungsten layer 72 to define a pattern of a metal interconnect. Thereafter, a dry etching process is performed to remove portions of the tungsten layer 72 and portions of the titanium nitride layer 68, both portions being not covered by the photoresist layer 73, to form a metal interconnect 74. Due to the excellent step coverage ability of the tungsten layer 72, a void is formed in the via hole 66 after forming the tungsten layer 72. However, the tungsten layer 72 has a sufficient thickness and thus seals an opening of the via hole 66 at a top end of the via hole 66 so as to prevent portions of the photoresist layer 73 from entering the void in the via hole 66. Consequently, no photoresist remains in the via hole 66 after removing the photoresist layer 73.

As shown in FIG. 15, a deposition process is then performed to form a second dielectric layer 76. Since no residual photoresist is in the via hole 66, abnormal phenomena, such as particles, defects and bubbles, are effectively prevented during the deposition process employed for the formation of the second dielectric layer 76, manufacturing processes are simplified, the etching back process of the tungsten layer, leading to residues and defects, is omitted, and the yield is improved.

However, this modified process still causes several problems, such as the more expensive manufacturing cost due to the greater thickness of the tungsten layer required, and the difficulty in smoothly depositing the second dielectric layer 76 during the deposition process due to an increased step height of the tungsten layer 72. Yield rates for subsequent processes are thus affected.

Therefore, it is very important to develop a method for forming a metal interconnect to not only prevent the photoresist residue, but also reduce the required thickness of the tungsten layer, so as to reduce the production cost, improve the planarization of the second dielectric layer, simplify the manufacturing processes and increase the product yield.

### SUMMARY OF THE INVENTION

It is therefore a primary objective of the present invention to provide a metal interconnect and a method for forming the metal interconnect so as to prevent photoresist residue.

According to the claimed invention, a first dielectric layer is positioned on a surface of a semiconductor substrate with at least one recess formed in the first dielectric layer. Then, a first titanium nitride layer, a tungsten layer and a second titanium nitride layer that seals an opening of the recess are sequentially formed on the surface of the recess. Thereafter, a photo-etching-process (PEP) is performed to form at least one metal interconnect in the first titanium nitride layer, the tungsten layer and the second titanium nitride layer. The second titanium nitride layer for sealing the opening of the recess is used to prevent photoresist from remaining in the recess during the photo-etching-process.

It is a feature of the present invention to form a first titanium nitride layer and a tungsten layer first, and then form a second titanium nitride layer with a poor step coverage ability to seal the opening of the via hole. Therefore, no photoresist remains in the via hole during the subsequent photolithography process for forming the metal interconnect. The required thickness for tungsten layer is thus prevented from being increase so as to reduce the production cost as the planarization of a second dielectric layer in subsequent process is improved. Since a tungsten etching back process is omitted in the present invention, the residues and defects are avoided, and the production yield is significantly improved. Moreover, the second titanium nitride layer atop of the tungsten layer is used not only as an anti-reflection layer (ARC layer) to decrease the difficulty in performing the photolithography process for the metal interconnect, but also as a glue layer to improve the adhering ability of the tungsten layer to the second dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 to FIG. 5 are schematic diagrams of forming either a metal interconnect or a via plug according to the prior art.

FIG. 6 to FIG. 11 are schematic diagrams of a modified method for forming a metal interconnect according to the prior art.

FIG. 12 to FIG. 15 are schematic diagrams of another modified method for forming a prior art metal interconnect.

FIG. 16 to FIG. 20 are schematic diagrams of forming a metal interconnect according to the present invention.

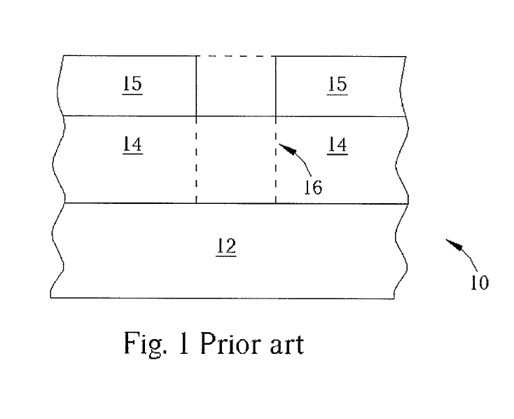

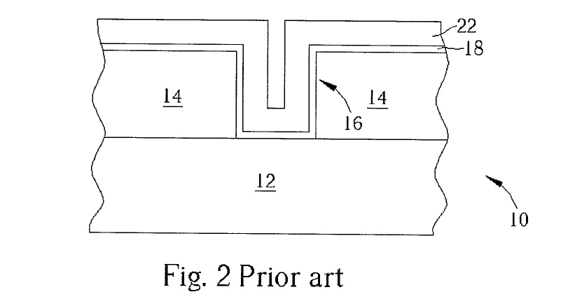

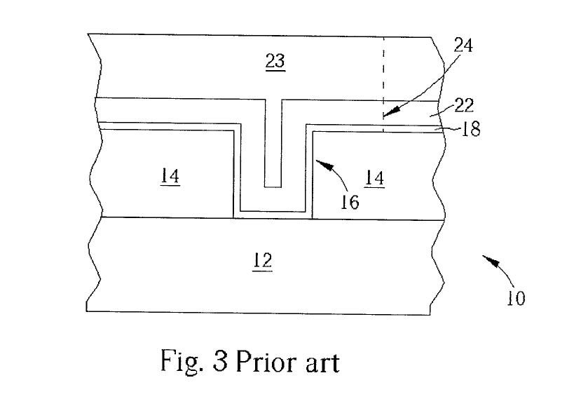

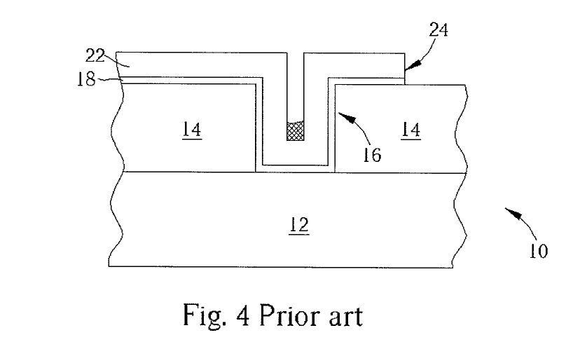

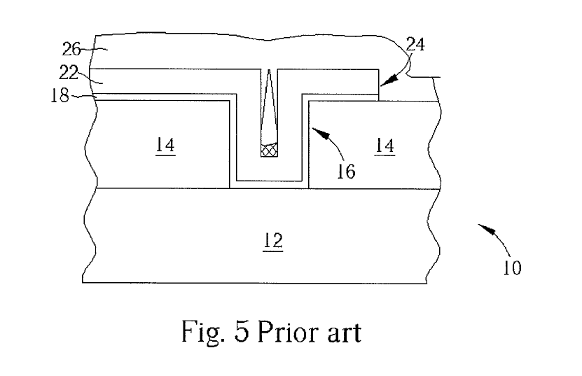

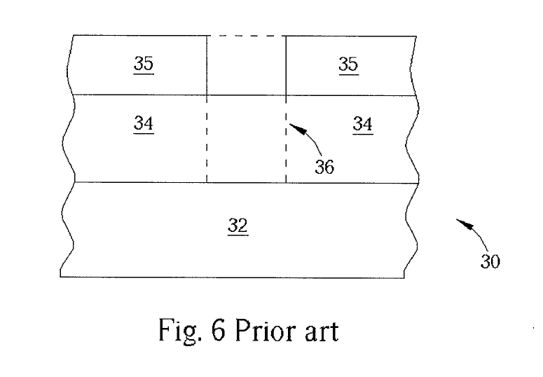

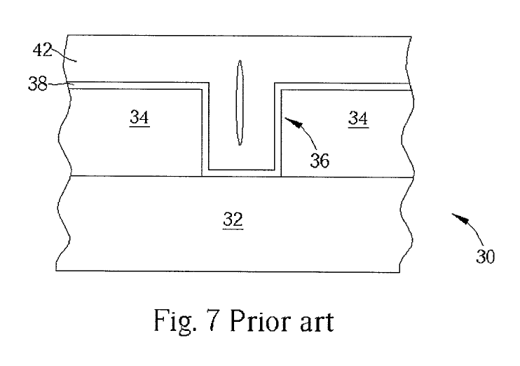

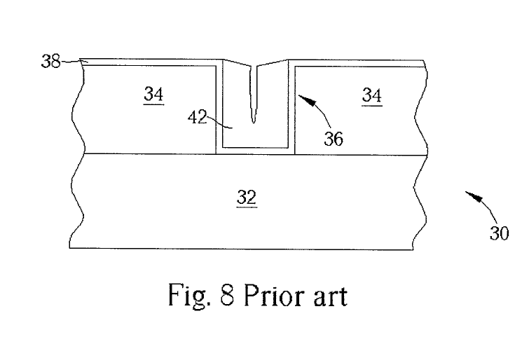

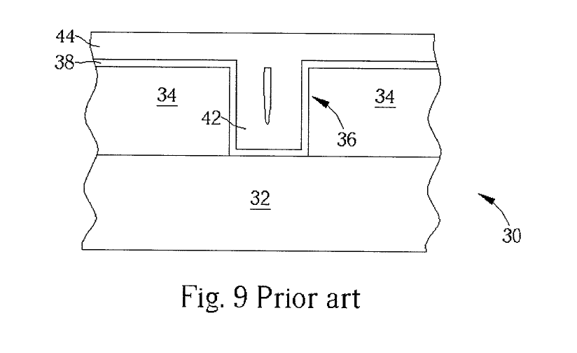

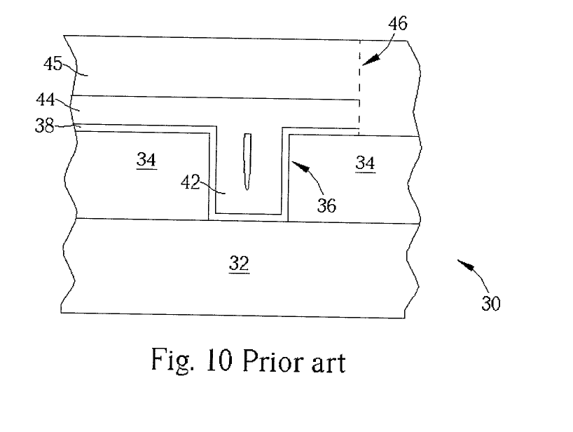

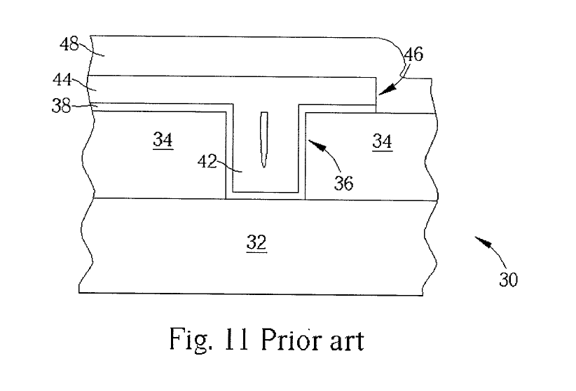

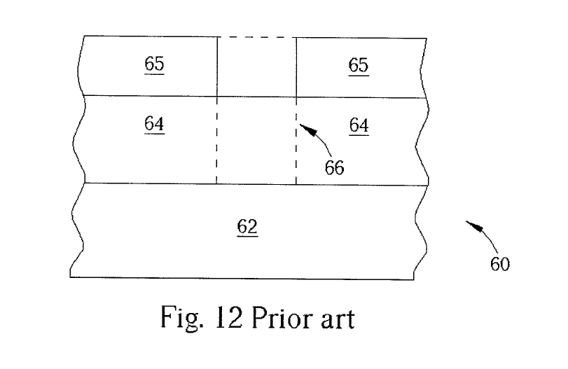

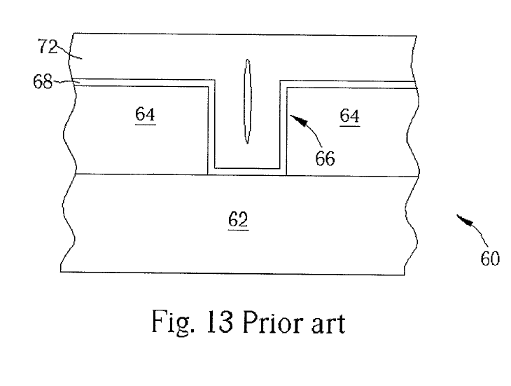

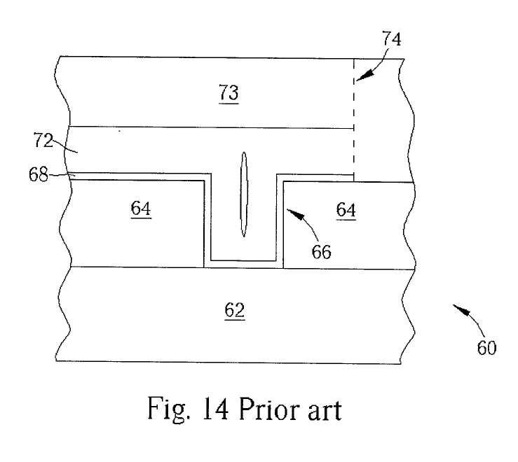

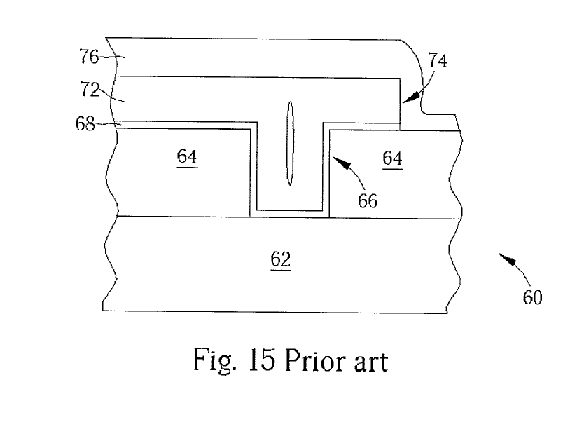

### DETAILED DESCRIPTION

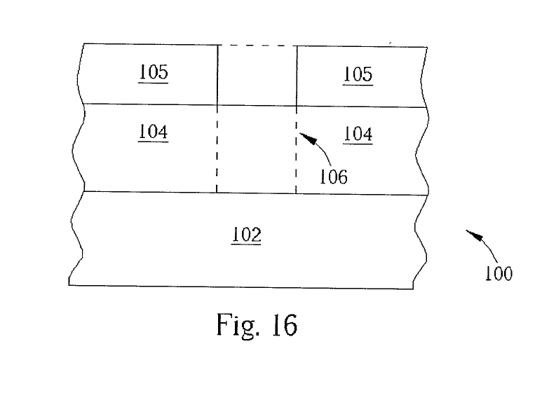

Please refer to FIG. 16 to FIG. 20 of schematic diagrams of forming a metal interconnect 118 according to the present invention. As shown in FIG. 16, a semiconductor wafer 100 comprises a substrate 102 and a first dielectric layer 104 covering the substrate 102. First, a photoresist layer 105 is coated on the surface of the first dielectric layer 104 followed by performing a photolithography process to define the site and dimensions of at least one recess in the photoresist layer 105. Then a dry etching process is performed to vertically remove portions of the first dielectric layer 104 along the defined pattern down to the surface of the substrate 102, so that a via hole 106 with two vertical side walls is formed. It is worth noticing that normally a metal layer (not shown), alternatively a conductive region (not shown), is on portions of the surface of the substrate 102 underneath the via hole 106. The same process is applied as well in the formation of a contact hole with either a source (not shown), a drain (not shown) or a gate (not shown) of a MOS transistor on portions of the surface of the substrate 102 underneath the contact hole.

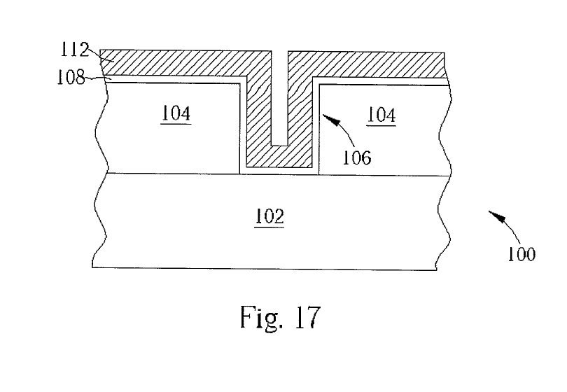

As shown in FIG. 17, a first titanium nitride layer 108, employed as a glue layer, is formed in the via hole 106 and atop the first dielectric layer 104 thereafter by performing a nitridation process or a reactive sputtering process. The nitridation process is to deposit a titanium layer with a specific thickness on a surface of a wafer by a DC Magnetron Sputter method first, and then place the wafer in an environment containing nitrogen or ammonia to nitridize the titanium layer to a titanium nitride layer at a high temperature. On the other hand, the reactive sputtering process is to ion bombard a titanium target by utilizing a reactive gas mixed with argon and nitrogen to sputter the titanium atoms from the titanium target. Then the titanium atoms react with the nitrogen atoms produced from a dissociation reaction in the plasma, and a titanium nitride deposition process therefore progresses on the wafer surface. Thereafter, a chemical vapor deposition (CVD) process is performed to deposit a tungsten layer (W layer) 112 with good step coverage ability on the first titanium nitride layer 108.

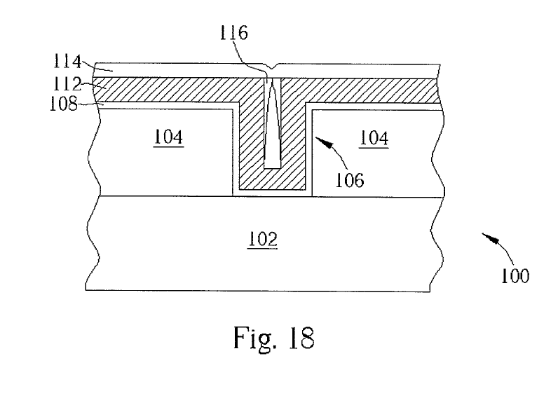

As shown in FIG. 18, then a reactive sputtering process is performed to form a second titanium nitride layer 114 on the tungsten layer 112. The reactive sputtering process, a physical vapor deposition process, is characterized by depositing a film with poor step coverage. Therefore the via hole 106 is not entirely filled with the sputtered metal, and a sealed void is thus formed in the via hole 106 as an opening of the via hole 106 is sealed by an overhang 116. Alternatively, the second titanium nitride layer 114 is replaced by a titanium layer or a titanium-tungsten-based layer (TiW-based layer) formed by a physical vapor deposition process since they are both characterized by poor step coverage ability and high temperature resistance.

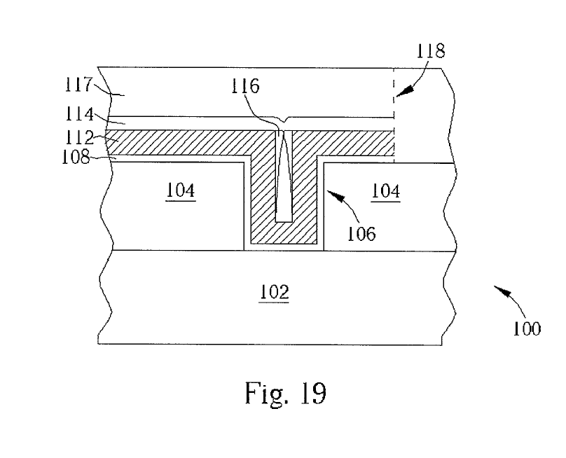

As shown in FIG. 19, a first photolithography process is then performed to form a patterned photoresist layer 117 atop the second titanium nitride layer 114 to define a pattern of a metal interconnect. Thereafter, a dry etching process is performed to remove portions of the second titanium nitride layer 114, portions of the tungsten layer 112 and portions of the first titanium nitride layer 108, all portions being not covered by the photoresist layer 117, to form a metal interconnect 118. Since the opening of the via hole 106 is sealed by the second titanium nitride layer 114, having a poor step coverage ability, no photoresist enters the via hole 106 during the formation of the photoresist layer 117. The photoresist layer 117 is then removed.

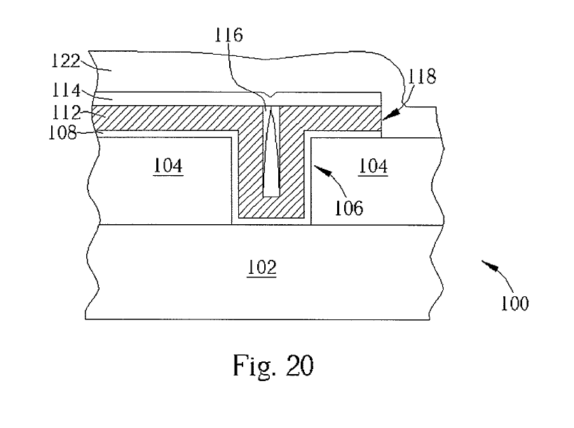

As shown in FIG. 20, then a deposition process is performed to form a second dielectric layer 122. Since no residual photoresist remains in the via hole 106, abnormal phenomena, such as particles, defects and bubbles, are prevented during the deposition process.

Since the present invention is employed to form a first titanium nitride layer and a tungsten layer first, and then to form a second titanium nitride layer with a poor step coverage ability to seal the opening of the via hole, no photoresist remains in the via hole during the photolithography process employed to form the metal interconnect. In addition, the required thickness for the tungsten layer in the present invention is not increased, so that problems of increasing production cost and defective planarization of the second dielectric layer are prevented. The residues and defects are avoided as well since an etching back process is omitted, and the production yield is therefore improved significantly. Moreover, the second titanium nitride layer atop the tungsten layer is used not only as an anti-reflection layer (ARC layer) to decrease the difficulties in performing the photolithography process for forming the metal interconnect, but also as a glue layer to improve the adhering ability of the tungsten layer 112 to the second dielectric layer 122.

In contrast to the prior art method for forming the metal interconnect, the method provded in the present invention is employed to form a first titanium nitride layer and a tungsten layer first, and then to form a second titanium nitride layer with a poor step coverage ability to seal the opening of the via hole. Therefore, no photoresist remains in the via hole, and abnormal phenomena, such as particles, defects and bubbles, are thus prevented during the photolithography process for forming the metal interconnect. In addition, the method provided in the present invention not only prevents the photoresist residues, but also reduces the required thickness of tungsten layer. Consequently, the manufacturing processes are simplified, the production cost is decreased, the planarization is improved, and the yield rate is increased. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming a metal interconnect, the method comprising:
providing a semiconductor substrate, the semiconductor substrate comprising a conductive area, a first dielectric layer covering the semiconductor substrate and the conductive area;
performing a photo-etching-process (PEP) on the first dielectric layer to form at least one recess in the first dielectric layer down to a surface of the conductive area;
forming a glue layer and a metal layer sequentially on surfaces of the first dielectric layer and the recess, the metal layer and the glue layer being not entirely filling the recess;
forming a material layer on the surface of the metal layer to seal an opening or the recess and form a void in the recess;
forming a patterned photoresist layer on the surface of the material layer to define at least one pattern of a metal interconnect;
performing an etching process to remove portions of the material layer, the metal layer and the glue layer not covered by the photoresist layer to form the metal interconnect;
removing the photoresist layer; and
forming a second dielectric layer to cover the metal interconnect and the first dielectric layer.

2. The method of claim 1 wherein both the first dielectric layer and the second dielectric layer comprises silicon dioxide (SiO₂).

3. The method of claim 1 wherein the glue layer has a stack structure comprising a titanium-silicon-based (TiSi₂-based) layer covered by a titanium nitride layer formed by utilizing a reactive sputtering process.

4. The method of claim 1 wherein the metal layer is a tungsten (W) layer.

5. The method of claim 4 wherein the tungsten layer is formed by utilizing a chemical vapor deposition (CVD) process.

6. The method of claim 1 wherein the material layer comprises a titanium nitride layer, a titanium layer and a titanium tungsten layer (TiW layer).

7. The method of claim 1 wherein the material layer is formed by utilizing a physical vapor deposition (PVD) process.

8. The method of claim 1 wherein the material layer is used as an anti-reflection layer (ARC layer).

9. The method of claim 1 wherein the material layer is used as a glue layer.

10. A method of forming a metal interconnect, the method comprising:
providing a semiconductor substrate, the semiconductor substrate comprising a conductive area, a first dielectric layer covering the semiconductor substrate and the conductive area;
performing a photo-etching-process (PEP) on the first dielectric layer to form at least one recess in the first dielectric layer down to a surface of the conductive area;
forming a first titanium nitride (TiN) layer and a tungsten (W) layer sequentially on surfaces of the first dielectric layer and the recess, the tungsten layer and the first titanium nitride layer being not filling the recess entirely;
forming a second titanium nitride layer on the surface of the tungsten layer to seal an opening of the recess;
forming a patterned photoresist layer on the surface of the second titanium nitride layer to define at least one pattern of a metal interconnect;
performing an etching process to remove portions of the second titanium nitride layer, the tungsten layer and the first titanium nitride layer not covered by the photoresist layer to form the metal interconnect;
removing the photoresist layer; and
forming a second dielectric layer to cover the metal interconnect and the first dielectric layer.

11. The method of claim 10 wherein both the first dielectric layer and the second dielectric layer comprises silicon dioxide (SiO₂).

12. The method of claim 10 wherein the first titanium nitride layer is formed by utilizing a reactive sputtering process and is used as a glue layer.

13. The method of claim 10 further comprising a deposition process for forming a titanium-silicon-based (TiSi₂-based) layer prior to the formation of the first titanium nitride layer.

14. The method of claim 10 wherein the tungsten layer is formed by utilizing a chemical vapor deposition (CVD) process.

15. The method of claim 10 wherein the second titanium nitride layer is formed by utilizing a physical vapor deposition (PVD) process to seal the opening of the recess so as to prevent the photoresist layer from remaining in the recess.

16. The method of claim 10 wherein the second titanium nitride layer is used as an anti-reflection layer (ARC layer).

17. The method of claim 10 wherein the second titanium nitride layer is used as a glue layer.

18. A method of preventing residue photoresist in a metal interconnect, the method comprising:
providing a semiconductor substrate, the semiconductor substrate comprising a conductive area, a first dielectric layer covering the semiconductor substrate and the conductive area;
performing a photo-etching-process (PEP) on the first dielectric layer to form at least one recess in the first dielectric layer down to a surface of the conductive area;
forming a glue layer and a tungsten (W) layer sequentially on surfaces of the first dielectric layer and the recess, the tungsten layer and the glue layer being not entirely filling the recess;
forming a titanium nitride (TiN) layer on the surface of the tungsten layer to seal an opening of the recess;
forming a patterned photoresist layer on the surface of the titanium nitride layer to define at least one pattern of a metal interconnect;
performing an etching process to remove portions of the titanium nitride layer, the tungsten layer and the glue layer not covered by the photoresist layer to form the metal interconnect;
removing the photoresist layer; and
forming a second dielectric layer to cover the metal interconnect and the first dielectric layer;
wherein the titanium nitride layer is formed by utilizing a deposition process, having a poor step coverage ability, to seal the opening of the recess so as to prevent the photoresist layer from remaining in the recess.

19. The method of claim 18 wherein both the first dielectric layer and the second dielectric layer comprises silicon dioxide (SiO₂).

20. The method of claim 18 wherein the glue layer has a stack structure comprising a titanium-silicon-based (TiSi₂-based) layer covered by a titanium nitride layer formed by utilizing a reactive sputtering process.

21. The method of claim 18 wherein the tungsten layer is formed by utilizing a chemical vapor deposition (CVD) process.

22. The method of claim 18 wherein the titanium nitride layer is used as an anti-reflection layer (ARC layer).

23. The method of claim 18 wherein the titanium nitride layer is used as a glue layer.
